(19) United States
(12) Patent Application Publication
(10) Pub. No.: US 2009/0216468 A1
(43) Pub. Date: Aug. 27, 2009

(54) Dual Mode Vector Network Analyzer

(76) Inventor: Keith Frederick Anderson, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/035,310

(22) Filed: Feb. 21, 2008

(51) Int. Cl. G01R 31/00

(52) U.S. Cl. 702/57

(57) ABSTRACT

A multimode network analyzer (VNA) and the method of using the same are disclosed. The VNA includes a signal input port that receives a test signal, an LO signal generator, a mixer, an IF filter and a processor. The LO signal generator generates a mixer LO signal from a mixer input test signal, the LO signal generator having first and second modes. The mixer LO signal is substantially a first periodic signal in the first mode and a second periodic signal having a plurality of harmonically related tones in the second mode. The mode that is currently operative is determined by a mixer control signal. The mixer is driven by the LO signal and has an output that is filtered by the IF filter to generate an IF signal. The processor analyzes the IF signal to determine a parameter characterizing the test signal and outputs that parameter.

### BACKGROUND OF THE INVENTION

Vector network analyzers (VNAs) are used to characterize electronic circuits. Typically, the transmission and reflection of an input signal by the circuit being characterized is measured as a function of frequency. Consider a circuit having two ports. A signal is input to the first port and the amplitudes and phases of the signals leaving the first and second ports are measured as a function of frequency. The input signal is then applied to the second port and the measurements repeated as a function of frequency. The measured values are then used to compute the scattering parameters for the circuit in question. To simplify the following discussion, it will be assumed that the circuit of interest has two ports and that a two-port network analyzer is utilized.

In one class of prior art VNA, an RF signal is applied to the device under test (DUT) and each signal of interest from the device is input to a receiver that has a mixer in which the signal is mixed with a local oscillator (LO) signal to down convert the signal to an IF signal that is then filtered to provide a measurement signal that is digitized by the receiver. This type of VNA will be referred to as a mixing VNA in the following discussion. In a mixing VNA, the LO frequency is shifted at each frequency measurement such that the output of interest from the mixer is always within a narrow frequency range corresponding to the filter. This arrangement reduces the noise in the measured signal, since the filter can be a very narrow bandpass filter, and the noise typically has a very wide frequency band. Accordingly, this type of VNA is particularly well suited to applications in which a very large dynamic range is required. It should also be noted that the RF frequency could be swept with the LO or held constant depending on the type of circuit being characterized.

Consider the case in which the DUT is itself a bandpass filter. To characterize the filter, the attenuation and phase shift introduced by the filter as a function of the frequency of the input signal to the filter is measured. When the input signal has a frequency within the pass band of the filter, the output transmission of the filter will be high and the corresponding signal strength will also be large. However, when the frequency of the input signal is outside the pass band of the filter or on the edges of the pass band, the transmitted signal will be attenuated by several orders of magnitude. In this case, the output signal can be lost in the system noise. Since a mixing VNA uses a very narrow bandpass filter in the receiver, the contribution of the noise is significantly reduced and accurate measurements can be made in the regions on the edge of the pass band or outside the pass band for which the filter is designed.

Now consider the case in which the output of the DUT for a particular input signal must be measured over a very wide range of frequencies spanning tens of GHz at frequency values that differ by only a few MHz. For example, the input signal could consist of a repetitive signal having 400 harmonics spanning a 20 GHz frequency range. In essence, the input signal consists of 400 narrow frequency signals having a 50 MHz spacing. In principle, this measurement could be accomplished by setting the LO frequency to a frequency near each of the harmonic frequencies, make the required measurements, and then move the LO frequency to the next frequency, wait for the LO frequency to stabilize, and repeat the measurements until all 400 separate measurements are made. In many case, there are limitations on the time available to make the complete set of measurements. For example, if the DUT is sensitive to temperature, the measurements must be made before the DUT changes temperature significantly.

Furthermore, to provide the phase information, the relative phases of the different LO signals used to measure each harmonic must also be known. This further complicates this type of measurement by requiring additional calibration schemes and hardware.

Hence, a different type of VNA is preferred for making measurements over large frequency ranges. This second type of VNA will be referred to as a sampling VNA, since the VNA operates in a manner that is analogous to a sampling oscilloscope. This type of VNA is described in detail in co-pending U.S. patent application Ser. No. 11/848,114 filed on Aug. 30, 2007, which is hereby incorporated by reference. For the purposes of this discussion, it is sufficient to note that a sampling VNA operates by replacing the conventional single tone LO signal with a signal that includes multiple tones having frequencies chosen such that the output of the mixer includes a frequency compressed version of the input signal. The output of the mixer is filtered through a bandpass filter having a pass band that is chosen such that the frequency compressed signal in the IF signal is passed by the filter while the remaining mixing products are blocked. The output of the bandpass filter is then digitized using an analog-to-digital converter and analyzed to provide the amplitude and phase of each of the harmonics in the input signal to the VNA.

A sampling VNA provides the desired information in a small fraction of the time that would be needed to measure the input signal one frequency at a time. However, the noise floor in a sampling VNA is much higher than the noise floor in a mixing VNA for two reasons. First, the pass band of the IF filter must be large enough to pass the frequency compressed IF signal, which has a frequency range that is much larger than the IF signal corresponding to the single down converted tone generated in a mixing VNA. Since the noise power tends to be constant as a function of frequency, the amount of noise in the IF signal increases with the bandwidth of the pass band of the IF filter. Accordingly, the amount of noise that is present for each tone in the LO signal is much greater than the corresponding noise in a mixer VNA. Second, the LO signal can be viewed as having a number of different harmonics. Each LO harmonic down converts a corresponding frequency region in the input signal along with the noise in that frequency range. The noise contributions from each of the down converted frequency regions within the pass band of the IF filter are added together at the output of the mixer, and hence, the noise levels are further increased. Accordingly, sampling VNAs are most useful in measurement problems in which very large frequency ranges must be covered and high signal-to-noise ratio in the measured signals are not required.

### SUMMARY OF THE INVENTION

The present invention includes a multimode network analyzer and the method of using the same. In one embodiment of the invention, the network analyzer includes a signal input port for receiving a test signal. An LO signal generator, a mixer, an IF filter and a processor. The LO signal generator generates a mixer LO signal from a mixer input test signal, the LO signal generator having first and second modes. The mixer LO signal is a first periodic signal in the first mode and a second periodic signal having a plurality of harmonically related tones in the second mode. The mode that is currently operative is determined by a mixer control signal. The mixer is driven by the LO signal and has an output that is filtered by the IF filter to generate an IF signal. The processor analyzes the IF signal to determine a parameter characterizing the test signal and outputs that parameter. In another embodiment of the invention, the mixer input test signal includes a periodic signal having a period T, and the mixer LO signal generator includes a pulse generator that generates one pulse every T′ seconds, where T′ is determined by T. In another embodiment of the invention, the pulse has a duration determined by a width control signal. In yet another embodiment of the invention, the mixer LO signal includes a repetitive multi-pulse signal in the second mode, the multi-pulse signal having a period determined by the mixer input test signal. In a still further embodiment of the invention, the processor makes a first measurement with the LO generator in one of the first and second modes and utilizes that measurement to obtain a second measurement with the LO generator in the other of the first and second modes.

In another embodiment of the invention, the VNA includes first and second mixer channels and a measurement channel input port. Each mixer channel includes a coupler for applying a portion of a signal to a mixer corresponding to that channel, the mixer being driven by the mixer LO signal, and an IF filter that filters an output of the mixer to generate an IF signal corresponding to that mixer channel. The coupler in the first mixer channel of the measurement channel is connected to the measurement channel input port and a device port, and the coupler in the second mixer channel applies a portion of a signal received on the device port to the mixer in the second mixer channel. The processor analyzes the IF signals from the first and second mixer channels to determine a parameter characterizing the DUT and outputs that parameter.

### BRIEF DESCRIPTION OF THE DRAWINGS

FIG. 1 illustrates one embodiment of a receiver with a multi-tone or multi-pulse local oscillator.

FIG. 2 illustrates an exemplary signal S(t) having a fundamental frequency of 50 MHz and 400 harmonics.

FIG. 3 illustrates a multipulse LO signal generator according to one embodiment of the present invention.

FIG. 4 illustrates a multi-tone signal generator.

FIG. 5 illustrates one embodiment of a multi-pulse signal generator for use in the present invention.

### DETAILED DESCRIPTION OF THE PREFERRED EMBODIMENTS OF THE INVENTION

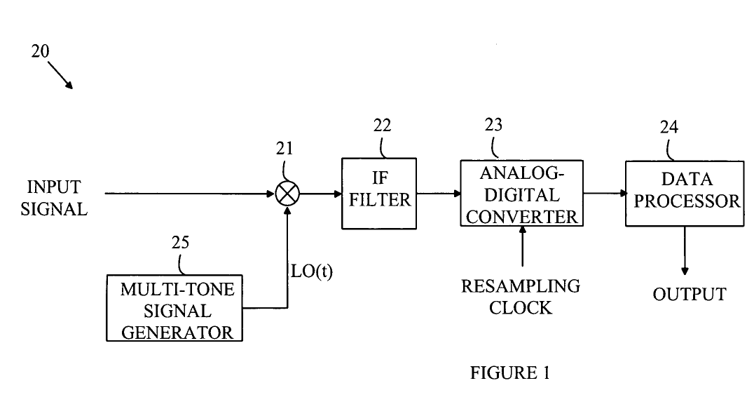

The manner in which the present invention provides its advantages can be more easily understood with reference to FIG. 1, which illustrates the principle on which a sampling VNA operates. FIG. 1 illustrates one embodiment of a receiver with a multi-tone or multi-pulse local oscillator [LO]. The input signal to receiver 20 is mixed with a repetitive LO signal that will be discussed in more detail below. The output of mixer 21 is low pass filtered through filter 22 and digitized by analog-to-digital converter 23. The output of analog-to-digital converter 23 is processed by data processor 24 to provide measurements of the amplitude and phase of the input signal's frequency components.

Denote the input signal to mixer 21 by S(t) and the output of low pass filter 22 by S′(t). It is assumed that S(t) is a periodic signal, and hence, represented by a harmonic series. If the tones in the LO signal and frequency cutoff of filter 22 are properly chosen, S′(t) will have a frequency component corresponding to each harmonic in S(t). Furthermore, by measuring the amplitude and phase of each frequency component in S′(t), the amplitude and frequency of each harmonic in S(t) can be determined.

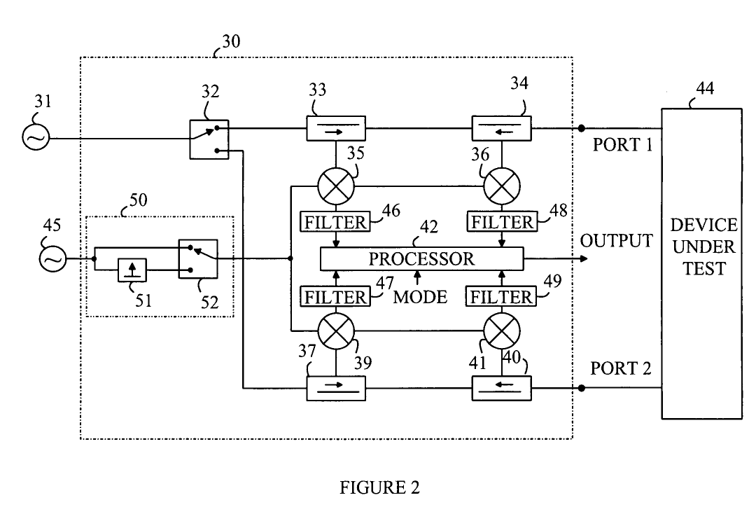

To better illustrate the manner in which the LO signal is constructed, refer to FIG. 2, which illustrates an exemplary signal S(t) having a fundamental frequency of 50 MHz and 400 harmonics. The spectrum consists of 400 peaks at frequency intervals of 50 MHz. For simplicity, in this example, it will be assumed that there is one tone in the LO signal for each harmonic of interest in S(t). The LO signal is also a periodic signal that is represented by a harmonic series. Consider the case in which the LO signal has a fundamental frequency of 50.001 MHz. Each of the harmonics in the LO signal will mix with each of the harmonics in S(t). In particular, the fundamental frequency in the LO signal will mix with the fundamental frequency of S(t) to produce a frequency component having a frequency of 1 KHz at the output of the mixer. The fundamental frequency of the LO signal will also mix with the higher harmonics in S(t) to produce frequency components having frequencies above 50 MHz. It will be assumed that these higher order mixing products are removed by filter 22. Similarly, the harmonic of the LO signal at 100.002 MHz will mix with the harmonic of S(t) at 100 MHz to produce a mixing product at a frequency of 2 KHz in S′(t), and so on. The highest harmonic in S(t) at 20 GHz will give rise to a frequency component in S′(t) at 400 KHz. If the amplitudes of the various harmonics in the LO signal are equal to one another, S′(t) will be a frequency compressed version of S(t) and have a frequency spectrum that is confined to 400 KHz. In general, the amplitudes of the frequency components in the LO spectrum are not identical to one another; however, the amplitudes and phases of the frequency components in the LO spectrum can be determined by suitable calibration measurements and used to determine the amplitudes and phases of the harmonics in S(t).

Consider an input signal that is repetitive with a period of Tᵢₙ. Assume that the output of multi-tone or multi-pulse signal generator 25 is also a repetitive signal of period T_{LO} where T_{LO} is slightly different from Tᵢₙ. In this case both the input and LO signals can be represented as harmonic series of the form:

$$S ( t ) = {\sum }_{k} {A}_{k} {e}^{( j k {ω}_{in} t + {ϕ}_{k} )}$$

$$LO ( t ) = {\sum }_{k} {B}_{k} {e}^{( j k {ω}_{LO} + {φ}_{k} )}$$

Here, j=\sqrt{−1}, ωᵢₙ=2π/Tᵢₙ, •_{LO}=2π/T_{LO}, and the φₖ and φₖ are the phases of the k^{th} harmonics in the input signal and LO input, respectively. The output of mixer 21 contains all possible cross-products of S(t) and LO(t). In particular, S′(t) can be written in the form:

$${S}^{′} ( t ) = {\sum }_{k} {B}_{k} {A}_{k} {e}^{( j k {ω}_{C} t + d {ϕ}_{k} )} + other frequency terms$$

Here ω_{c}=|ωᵢₙ−ω_{LO}|. Hence, S′(t) will include a harmonic having frequency kω_{c} corresponding to the harmonic having frequency kωᵢₙ in the input signal. Denote the frequency of highest harmonic of interest in the input signal by Nωᵢₙ. It should be noted that each harmonic in the input signal will also be represented by other terms that have frequencies greater than Nω_{c}. The unwanted higher frequency terms can be eliminated by IF filter 22. In general, the cutoff frequency of IF filter 22, C, is set such that C>Nω_{c}. The upper limit on C is determined by the particular analog-to-digital converter used.

The signal, S′(t), can be viewed as a frequency-compressed version of S(t). The compression factor is ωᵢₙ/ω_{c}. All of the amplitude and phase information of each of the harmonics in the input signal can be obtained from the amplitude and phase of the corresponding harmonic in S′(t), provided the amplitudes and phase of the harmonics in the LO signal are known. The fundamental frequency of the frequency-compressed signal is ω_{c} and dφₖ is the phase of the k^{th} harmonic of the frequency-compressed signal. The constants Bₖ and the phases associated with the tones in the LO signal can be measured by applying a known input signal to the mixer and measuring the amplitude and phase of each harmonic in the compressed signal. Hence, the Fourier transform of the filter output can be used to obtain the amplitudes, Aₖ and the phases, φₖ of S(t). The analog-to-digital converter needs to operate at a frequency that is sufficient to capture the frequency information in the filter output without significant aliasing of higher frequency signals. Hence, it must at least sample the filter output at a frequency twice the cutoff frequency of the IF filter. Since analog-to-digital converter 23 samples S′(t) more than once per period of the LO signal, analog-to-digital converter 23 captures more of the signal energy than a sampling scope. In addition, it should be noted that analog-to-digital converter 23 does not need to be synchronized to the LO signal.

In the above example, there is one harmonic in the LO signal for each harmonic of interest in the input signal. However, in the more general case, the number of harmonics in the LO signal can be considerably more or less than the number of harmonics of interest in the input signal. Similarly, there was one frequency component in S′(t) for each harmonic of interest in the input signal. However, depending on the particular LO signal utilized, some of the harmonics in the input signal may be represented by more than one harmonic in S′(t). That is, S′(t) may have more than N harmonics. The additional components can be ignored or utilized to provide an improved estimate of the amplitude and frequency of the corresponding harmonic in the input signal. Finally, it should be noted that the number of harmonics in the LO signal could differ from the number of harmonics of interest in the input signal. For example, one tone in the LO signal could down convert multiple harmonics in the input signal if the cutoff of the low pass filter is correctly chosen.

Embodiments of the present invention are based on the observation that a VNA that can perform both mixing mode and sampling mode operations can be constructed by augmenting a conventional mixing mode VNA with a pulse generator to provide the LO signal needed to operate in the sampling mode and a mode changing switch. Refer now to FIG. 2, which illustrates a dual mode VNA according to one embodiment of the present invention. VNA 30 is a two port VNA that is adapted for making measurements of two ports on a DUT 44. In each measurement, an RF signal generated by RF signal generator 31 is applied to one of the ports on DUT 44 and the signals leaving that port and a second port are analyzed by VNA 30. The port that is to receive the RF signal is determined by switch 32. In the example shown in FIG. 2, the RF signal is applied to port 1 of DUT 44. However, embodiments in which each port is connected to a separate test input signal port and the selection of which port receives the RF signal is made manually could also be constructed.

The RF signal that is applied to DUT 44 is measured prior to applying the signal to DUT 44 by coupling a fixed fraction of the RF signal energy to a mixer that receives an LO signal from LO generator 50. In the example shown in FIG. 2, the RF signal is measured by coupling the RF signal to mixer 35 via an unidirectional coupler 33. When the RF signal is applied to port 2, the RF signal is measured by coupling the RF signal to mixer 39 via unidirectional coupler 37. The output of mixers 35 and 39 are filtered by bandpass filters 46 and 47, respectively, to eliminate the higher mixing products. The outputs of filters 46 and 47 are then processed by processor 42, which includes an analog-to-digital converter that digitizes the output of the filters that is then analyzed to determine the amplitude and phase of the RF signal components of interest that are being applied to DUT 44.

The signals that leave the two ports of DUT 44 are coupled to mixers 36 and 41 by unidirectional couplers 34 and 40, respectively. These signals are mixed with the LO signal from LO generator 50 and filtered through IF filters 48 and 49, respectively. The outputs of filters 48 and 49 are then analyzed by processor 42 to determine the amplitude and phase of each of the harmonics of interest in the signal from DUT 44. The bandpass of filters 46-49 depend on the mode in which VNA is operating.

As noted above, VNA 30 can operate in two modes, a sampling mode and a conventional mixing mode that will be referred to simply as the mixing mode in the following discussion. The specific mode that is operational at any given time is provided by a mode signal that is under the control of the user of VNA 30. In the mixing mode, switch 52 in LO generator 50 is set such that the signal from a monotone signal generator 45 is applied to the mixers as the LO signal. In this case, the filter in processor 42 is set to be a narrow bandpass filter that transmits only the mixing product of the LO monotone signal and the RF signal tone. The LO frequency is set such that the mixing product in question is down converted to an IF frequency that can be analyzed to provide both the amplitude and phase of the RF signal that is input to DUT 44 and the signals that are returned from DUT 44.

In the sampling mode, the signal from signal generator 45 is converted to a signal having a plurality of harmonics so that the LO signal applied to the mixer is now a multi-tone signal having tones at the appropriate frequencies to down convert the harmonics of interest in the RF signal. The manner in which the signal from the signal generator is converted to a multi-tone signal by signal generator 51 will be discussed in more detail below. In the sampling mode, the pass band of filters 46-49 is increased to assure that all of the mixing products of interest are digitized by processor 42. In any given mode, the pass bands of filters 46-49 are the same.

The manner in which the multi-tone LO signal is generated from the monotone signal from signal generator 45 will now be discussed in more detail. For the sampling mode to operate properly, the multi-tone LO signal must have a plurality of harmonics at predetermined frequencies. In addition, each of the LO harmonics of interest must have sufficient power to provide mixing products with sufficient signal-to-noise ratios to allow the accurate measurement of the amplitude and phases of the harmonics in the RF signal and signals from the DUT that correspond to that LO harmonic. The fundamental frequency of the LO harmonic series is preferably determined by the frequency of the signal from signal generator 45, which, in general, will be related to the fundamental frequency of the RF signal.

The relative amplitude of the harmonics is preferably the same; however, some variation in amplitude can be accommodated by appropriate calibration. In general, there is a limit to the voltage that can be input to the mixer. This limit places a limit on the maximum amplitude of the LO harmonics. The noise levels in the output of the mixer places a limit on the minimum useable amplitude for the harmonics. Hence, the LO harmonics of interest must have amplitudes that are between these two limits.

The simplest circuit for signal generator 51 is a circuit that generates a square wave having a predetermined width on each cycle of the signal from generator 45. This type of circuit is functionally equivalent to a conventional “one shot” circuit that triggers on a particular edge at a predetermined amplitude on the sine wave generated by signal generator 45. At high frequencies a step recovery diode can be used in place of a one shot.

The ratio of the width of the pulse to the period of the pulse, i.e., the period of signal generator 45, determines the number of useable harmonics in the LO signal. In general, the amplitudes of the harmonics decrease with frequency until a null is reached. The location of the null and rate of decrease of the harmonic amplitudes with frequency depend on the relative width of the pulse. A narrow pulse provides more harmonics with similar amplitudes; however, the power in any given harmonic is decreased relative to the harmonics obtained with a wider pulse. As noted above, the mixers constrain the maximum amplitude of the pulse that can be utilized; hence, there is a minimum width for a single pulse LO signal at which the harmonics will no longer have sufficient amplitude to be above the noise floor.

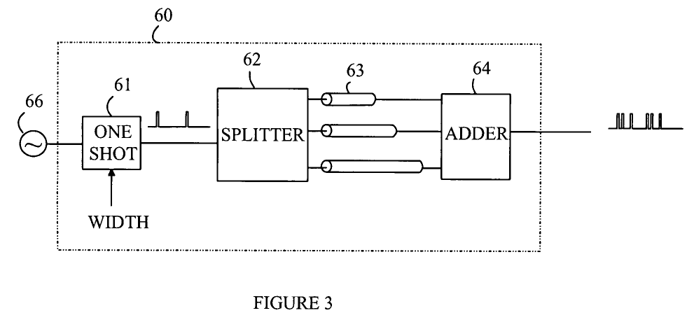

If the number of LO harmonics that are needed for a particular application is small, an LO signal that consists of one pulse per period can be utilized. However, if the number of harmonics needed is too large for a single pulse LO signal, an LO signal having a more complex structure must be utilized. One method for increasing the power in the harmonics utilizes a multipulse LO signal in which the number of pulses per period of the LO fundamental frequency is greater than one. Refer now to FIG. 3, which illustrates a multipulse LO signal generator according to one embodiment of the present invention. Pulse generator 60 includes a one shot 61 that generates a single square wave having a width determined by a signal input thereto on each cycle of a sine wave generated by signal generator 66. The output of one shot 61 is divided into three pulse trains by splitter 62. Each pulse train is input to a corresponding delay line such as delay line 63. The delays provided by each delay line are different from one another. The outputs of the delay line are combined by adder 64 to provide an output signal that now has three pulses per cycle.

It should be noted that the limitations on the maximum voltage allowed at the input to the mixer applies to the output of adder 64. Hence, the output of one shot 61 can be three times this limit, since the pulses from one shot 61 will be reduced in power by a factor of three by splitter 62. Accordingly, the amplitude of the harmonics in the mixer can be increased. The actual amplitudes of the harmonics in the resulting LO signal will depend on the time delay between the individual pulse trains. While the exemplary signal generator shown in FIG. 3 has three delay lines, it is to be understood that other numbers of delay lines could be utilized.

The above-described embodiments utilize an LO signal that consists of one or more square waves per cycle of the LO fundamental frequency. However, other shapes of pulses could be utilized if the pulses are easily generated by a circuit that can be triggered with the oscillator used to set the LO fundamental frequency. Since the shape of the pulse determines the distribution of energy in the LO harmonics, the shape of the pulse can be used to provide other energy distributions.

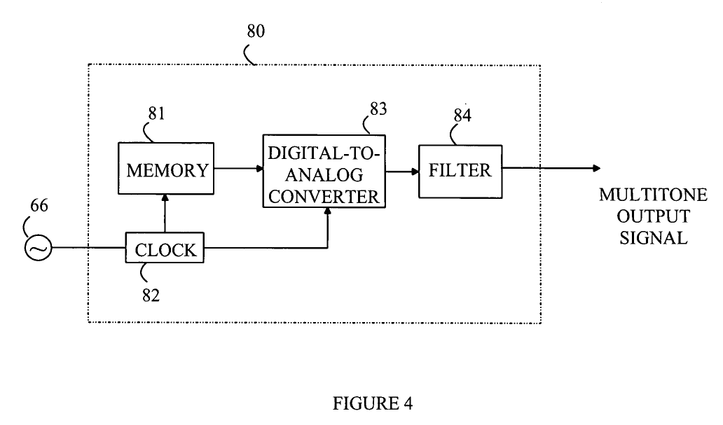

In general, if the desired harmonics and their relative amplitudes and phases are known, a multi-tone signal of the desired frequency spectrum and phase relationships could be synthesized digitally by generating each sine wave numerically and mathematically adding the individual sine waves with the desired amplitudes and phases. Refer now to FIG. 4, which illustrates a multi-tone signal generator 80 that utilizes this approach. The numerically generated digital signal is stored in a memory 81 as a sequence of amplitudes, the address of each amplitude specifies the order in which the value is to be read out of the memory. The address of the memory is supplied by a clock 82 that sequentially updates the address register in memory 81 and causes the value stored at the location specified by the address to be output to digital-to-analog converter 83. The clock also triggers digital-to-analog converter 83 causing the digital-to-analog converter to output a voltage specified by digital input thereto. The output of digital-to-analog converter 83 is then filtered by filter 84 to smooth out the steps in the output of digital-to-analog converter 83. The clock period is determined by signal generator 66 such that a repetitive signal of the desired period can be obtained.

Unfortunately, to provide a multi-tone signal with harmonics in the tens of GHz, the digital-to-analog converter must be capable of converting values at a rate of tens of GHz. Digital-to-analog converters having such high conversion rates are either not available or too costly for many applications of interest. Hence, at very high frequencies a different form of multi-tone signal generator is preferred.

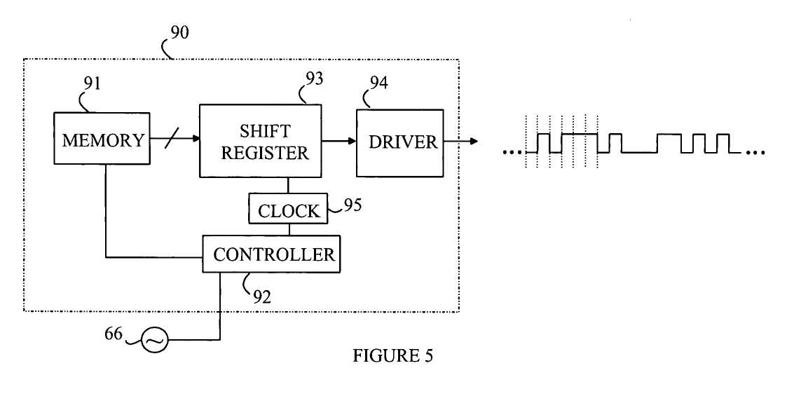

One type of signal that can be generated digitally at rates significantly above those obtainable using digital-to-analog converters is a multi-pulse signal generator. The multi-pulse signal generator produces a repetitive waveform of period T_{LO} consisting of a binary signal that switches between two voltages, V1 and V2 multiple times in the period of the signal generator 66. For the purposes of this discussion, a multi-pulse signal is defined to be a signal that takes on one of two voltages at any given time except for the times at which the signal is transitioning between these two values. Refer now to FIG. 5, which illustrates one embodiment of a multi-pulse signal generator 90 for use in the present invention. The multi-pulse signal is specified by a sequence of bits that are stored in a memory 91. To improve the speed of the multi-pulse signal generator, the sequence is divided into multi-bit words within memory 91. Each word is transferred in parallel to a high-speed into a high speed shift register 93 when the previous contents of the shift register have been read out. At each clock pulse, the shift register 93 selects the next bit of the parallel input word in sequence, and transfers it to the output. The output of shift register 93 forms the input to a driver 94 that converts the binary value to a voltage, a binary 0 being converted to V1 and a binary 1 being converted to V2. In the embodiment shown in FIG. 5, the multiplexer is implemented via a shift register that is shifted on each clock cycle from clock 95 that is under the control of controller 92. The clock rate is controlled by the output of signal generator 66

The maximum speed of multi-pulse signal generator 90 is determined by the rate at which bits can be read out of shift register 93. Shift registers that operate at tens of GHz are commonly used in telecommunication switches; hence, a multi-pulse signal generator can be constructed at a relatively low cost while still providing signals with harmonics in the tens of GHz. Since this rate is significantly higher than the rate at which digital-to-analog converters can operate, the multi-pulse signal generator allows the multi-tone mixer of the present invention to operate at higher signal input frequencies than would be possible with a conventional multi-tone signal.

A number of techniques can be employed to generate such multi-pulse patterns. For example, assume that the desired amplitudes and phases of the various harmonics are known. Denote the amplitudes and phases by Bₖ and φₖ, respectively, for k=1 to M. A combined digital signal D(n) is given by

$$D ( n ) = {\sum }_{k} {B}_{k} sin ( {knt}_{o} + {φ}_{k} )$$

where n runs from 1 to Y, the number of points in one cycle of the multi-tone digital signal. Here, t₀ is a constant that is chosen to provide the desired frequency resolution in the combined signal. This digital signal is then converted to a multi-pulse signal, P(n) by setting P(n)=1 if D(n)>0 and P(n)=0 if D(n)≦0. The frequency spectrum of P(n) can be shown to be approximately that of D(n). The differences are introduced by the approximation change in the calibration constants described above.

In many cases, a specific relationship between the phases, φₖ, is not required. If the multipulse signal is utilized to probe the frequency response of the device as discussed above, then the individual harmonics in the multipulse signal are treated separately in the analysis, and hence, the specific phase relationships between the harmonics in the multipulse signal do not enter into the analysis. In this case, the phases can be chosen such that the multipulse signal has less energy in harmonics that are different from the harmonics of interest.

The above-described embodiments provide a VNA that can be used in either the sampling or mixing mode by adding some additional hardware and software to a standard mixing mode VNA. In addition, having both modes available in the same apparatus enables measurements that would be difficult in a single mode VNA. For example, a sampling mode mixer can be used as a high-speed oscilloscope by measuring the amplitude and phase of each of the harmonics in a repetitive signal and then reconstructing the signal using an inverse Fourier transform. Unfortunately, as noted above, a sampling mixer introduces a significant amount of noise into the measurements, and hence, the resulting amplitude measurements of the harmonics in the signal have limited dynamic range. Similarly, a mixing mode network analyzer may be used to measure waveforms by measuring each frequency component and then combining the frequency components (amplitude and phase) to display the resulting waveform with very good amplitude dynamic range. Unfortunately, a mixing network analyzer cannot determine the phase difference between the various harmonics.

The present invention can be utilized to overcome these problems by using the VNA in the mixing mode to measure the amplitude of the harmonics, and hence, provide measurements with good amplitude dynamic range. The VNA is then used in the sampling mode to measure the phase difference between the harmonics. By combining these results, a low noise oscilloscope measurement is provided.

To use a VNA in sampling mode, an accurate measurement of the lowest frequency of the RF signal that is to be measured is needed to tune the LO frequency generator. If a large number of harmonics are to be measured in the sampling mode, the LO frequency needs to be quite accurate to assure that all of the desired mixing products are within the pass band of the mixer filter. The mixing mode of the VNA can be used to determine the correct frequency for the LO frequency generator by sweeping the LO frequency over a range of frequencies that includes the lowest frequency of interest in the RF signal. When the LO frequency is correctly set, all of the harmonics of interest will be seen in the RF signal that is input to mixer 35 or mixer 39 shown in FIG. 2. Alternatively, the LO can be swept to determine the fundamental of the RF signal, and then, signal generator 45 can be set at the desired frequency. The RF signal can then be measured in the sampling mode to provide a display that is analogous to a conventional oscilloscope, i.e., the RF signal amplitude as a function of time.

It should be noted that processor 42 could also control the frequency output of signal generator 45. To simplify the drawings, the connections between processor 42 and signal generator 45 have been omitted from the drawing. However, it is to be understood that processor 42 could control the signal generator as well as other components in VNA.

In the above discussion the filter that is utilized after the mixer is a bandpass filter or a low pass filter. To simplify the following discussion, the term IF filter will be defined to be either a low pass filter or a bandpass filter. The choice of mode will depend on the particular application.

In the above-described embodiments, signal generator 45 shown in FIG. 2 generates a signal that is substantially a single tone, i.e., a sinusoid. However, embodiments in which signal generator 45 generates other periodic signals could also be utilized. For example, signal generator 45 could also generate a square wave if a mixer with a limiting input is utilized in the VNA.

The above embodiments of the present invention utilize signal couplers to provide a signal path that is directional. However, other forms of coupling devices could be utilized including resistive dividers. Accordingly, the term “coupler” in the present application is defined to include any device that applies a portion of a signal in a first signal path to a second signal path.

Various modifications to the present invention will become apparent to those skilled in the art from the foregoing description and accompanying drawings. Accordingly, the present invention is to be limited solely by the scope of the following claims.

What is claimed is:

1. An apparatus comprising:
a first signal input port that receives a first input test signal to be applied to a device under test (DUT);
an LO signal generator that generates a mixer LO signal from a received second input test signal, said LO signal generator having first and second modes, said mixer LO signal being a first periodic signal in said first mode and a second periodic signal comprising a plurality of harmonically related tones in said second mode, said mode that is currently operative being determined by a mixer control signal;
a first measurement channel comprising first and second mixer channels and a first measurement channel input port, each mixer channel comprising;
a coupler that applies a portion of a signal to a mixer corresponding to that channel, said mixer being driven by said mixer LO signal; and
a IF pass filter that filters an output of said mixer to generate an IF signal corresponding to that mixer channel,
said coupler in said first mixer channel of said first measurement channel being connected to said first measurement channel input port and a first device port, and said coupler in said second mixer channel of said first measurement port applying a portion of a signal received on said first device port to said mixer in said second mixer channel; and
a processor that analyzes said IF signals from said first and second mixer channels to determine a parameter characterizing said DUT and outputs that parameter.

2. The apparatus of claim 1 wherein said first periodic signal comprises a square wave or a sinusoid.

3. The apparatus of claim 1 further comprising:
a second measurement channel comprising third and fourth mixer channels and a second measurement channel input port, each mixer channel comprising;
a coupler that applies a portion of a signal to a mixer corresponding to that channel, said mixer being driven by said mixer LO signal; and
an IF filter that filters an output of said mixer to generate an IF signal corresponding to that mixer channel,
said coupler in said third mixer channel of said second measurement channel being connected to said second measurement channel input port and a second device port, and said coupler in said fourth mixer channel of said second measurement port applying a portion of a signal received on said second device port to said mixer in said fourth mixer channel; and
a mechanism that selectively applies said first input test signal to either said first measurement channel input port or said second measurement channel input port to said first signal input port, wherein said processor also receives said IF signals from said third and fourth mixer channels.

4. The apparatus of claim 1 wherein a second input test signal comprises a periodic signal having a period T and wherein said mixer LO signal generator comprises a pulse generator that generates one pulse every T′ seconds, where T′ is determined by T.

5. The apparatus of claim 4 wherein said pulse has a duration determined by a width control signal.

6. The apparatus of claim 1 wherein said mixer LO signal comprises a repetitive multi-pulse signal in said second mode, said multi-pulse signal having a period determined by said second input test signal.

7. The apparatus of claim 1 wherein said processor makes a first measurement with said LO generator in one of said first and second modes and utilizes that measurement to obtain a second measurement with said LO generator in the other of said first and second modes.

8. The apparatus of claim 1 wherein said mixer LO signal comprises said second input test signal in said first mode.

9. The apparatus of claim 1 wherein said IF filters in said first, second, third, and fourth mixer channels have pass bands in said first mode that are different from said pass bands in said second mode.

10. The apparatus of claim 1 wherein said processor determines an amplitude and phase of a signal from said first device port.

11. An apparatus comprising:
a first signal input port that receives a test signal;
an LO signal generator that generates a mixer LO signal from a received second input test signal, said LO signal generator having first and second modes, said mixer LO signal being a first periodic signal in said first mode and a second periodic signal comprising a plurality of harmonically related tones in said second mode, said mode that is currently operative being determined by a mixer control signal;
a mixer driven by said mixer LO signal; and
an IF filter that filters an output of said mixer to generate an IF signal; and
a processor that analyzes said IF signal to determine a parameter characterizing said test signal and outputs that parameter.

12. The apparatus of claim 11 wherein said second input test signal comprises a periodic signal having a period T and wherein said mixer LO signal generator comprises a pulse generator that generates one pulse every T′ seconds, where T′ is determined by T.

13. The apparatus of claim 12 wherein said pulse has a duration determined by a width control signal.

14. The apparatus of claim 11 wherein said mixer LO signal comprises a repetitive multi-pulse signal in said second mode, said multi-pulse signal having a period determined by said mixer test signal.

15. The apparatus of claim 11 wherein said processor makes a first measurement with said LO generator in one of said first and second modes and utilizes that measurement to obtain a second measurement with said LO generator in the other of said first and second modes.

16. The apparatus of claim 11 wherein said mixer LO signal comprises said mixer input test signal in said first mode.

17. The apparatus of claim 11 wherein said processor determines an amplitude and phase of a component of said test signal.

18. A method for measuring a parameter of a test signal, said method comprising:
receiving said test signal;
providing a mixer that mixes said test signal with a mixer LO signal;
selecting one of a first LO signal and a second LO signal as said mixer LO signal, said first LO signal being a first periodic signal in said first mode and a second periodic signal comprising a plurality of harmonically related tones in said second mode;
filtering an output of said mixer with an IF filter to generate an IF signal;
analyzing said IF signal to determine a first parameter characterizing said test signal;
selecting the other of said first and second LO signals as said mixer LO signal, as least one characteristic of said selected first or second LO signal being determined by said first parameter;
filtering an output of said mixer with an IF filter to generate an IF signal; and
analyzing said IF signal to determine a second parameter characterizing said test signal and outputting data determined by said second parameter.

19. The method of claim 18 wherein said second LO signal comprises a pulse having a duration determined by a width control signal.

20. The method of claim 18 wherein said second LO signal comprises a repetitive multi-pulse signal.
